(19) United States
(12) Patent Application Publication
(10) Pub. No.: US 2015/0107653 A1
(43) Pub. Date: Apr. 23, 2015

(54) HIGH UTILIZATION PHOTO-VOLTAIC DEVICE

(71) Applicant: Dow Global Technologies LLC, Midland, MI (US)

(72) Inventors: Abhijit Namjoshi, Midland, MI (US); Marty Degroot, Middletown, DE (US); Leonardo Lopez, Midland, MI (US); Rebekah Feist, Midland, MI (US); Lindsey Clark, Midland, MI (US)

(21) Appl. No.: 14/402,349

(22) PCT Filed: May 29, 2013
(86) PCT No.: PCT/US2013/043109

§ 371 Date: Nov. 20, 2014

Related U.S. Application Data
(60) Provisional application No. 61/653,970, filed on May 31, 2012.

(51) Int. Cl. H01L 31/05; H01L 51/44; H01L 31/18; H01L 31/0376; H01L 31/0312; H01L 31/032; H01G 9/20; H01L 31/0445

(52) U.S. Cl. CPC H01L 31/0516; H01G 9/20; H01L 51/44; H01L 31/0445; H01L 31/03762; H01L 31/0312; H01L 31/0322; H01L 31/188
USPC 136/251; 136/256; 136/254; 136/244; 438/67

(57) ABSTRACT

An article of manufacture (400) includes a number of photovoltaic cells (102) forming a photovoltaic (PV) module circuit, with a first bus bar (106) electrically coupled to one extremity of the PV module circuit and a second bus (206) bar electrically coupled to a second extremity of the PV module. The bus bars (106, 206) are positioned on an opposing side of the PV cells (104, 204) from a light incident side of the PV cells.

### FIELD

The present invention relates to improved photo-voltaic devices, and more particularly but not exclusively relates to photo-voltaic devices having an enhanced utilization of the active solar area.

### INTRODUCTION

Presently known photo-voltaic (PV) devices include an active solar area which is the portion of the PV device where photons are received and converted to electrically available energy. In many devices, there is a non-utilized fraction of the active solar area that is reserved for, and/or areas that are screened by, electrical connection assembly elements such as a bus bar. Accordingly, certain types of known PV devices cannot utilize a significant fraction of the active solar area for the capture of photons. In certain applications, for example PV devices integrated into building products where the application surface area is predetermined, unit capture of solar energy by area is a priority and can affect whether an installation is economically viable. It is also desirable with building integrated PV devices that the PV device fit into the same form factor as the original product, for example a roofing shingle integrated PV device should be interchangeable with the physical space of a roofing shingle or a group of roofing shingles.

Among the literature that can pertain to this technology includes WO 2009/006230 A2, and EP1544921A1.

### SUMMARY

The present disclosure in one aspect includes an article of manufacture including a photovoltaic (PV) module having at least one PV cell, a number of conductive elements electrically coupled to the at least one PV cell and forming a module circuit, a first bus bar coupled to a first electrical extremity of the module circuit and a second bus bar coupled to a second electrical extremity of the module circuit. The module further includes a light incident side, and a PV cell from the at least one PV cell is positioned between the light incident side and the first bus bar, and a PV cell which may be the same or a distinct PV cell from the at least one PV cell is positioned between the light incident side and the second bus bar.

Additional or alternative aspects of the disclosure may be further characterized by any one or more of the following features: the PV module having a number of PV cells, each adjacent pair from the PV cells having a dielectric positioned therebetween, where the conductive elements are each electrically coupled to at least one PV cell and electrically connect the PV cells, and where a first PV cell is interposed between the first bus bar and the light incident side and a second PV cell is interposed between the second bus bar and the light incident side, the first bus bar electrically coupled to the light incident side of the first PV cell, and a bus bar separation dielectric positioned between the first bus bar and the first PV cell; the bus bar separation dielectric further including a portion positioned on an outer portion of the first PV cell; the second bus bar electrically coupled to an opposing side of the second PV cell from the light incident side; a dielectric positioned between the second bus bar and the second PV cell; the module circuit arranged as parallel, series, or series-parallel; the module circuit, first bus bar, and second bus bar forming an electrical assembly, the electrical assembly encapsulated in an encapsulation material; a structural backing defining a unit shape of a construction material unit, and an encapsulation material positioned between the structural backing and the second bus bar, where the second bus bar is interposed between the encapsulation material and the second PV cell; a structural backing defining a unit shape of a construction material unit, and an encapsulation material positioned between the structural backing and the second bus bar, where the second bus bar is interposed between the encapsulation material and the second PV cell and the first bus bar is interposed between the encapsulation material and the first PV cell; and/or a number of PV modules each having a corresponding module circuit, where the first bus bar is electrically coupled to a first electrical extremity of each of the corresponding module circuits, and where the second bus bar is electrically coupled to a second electrical extremity of each of the corresponding module circuits.

An additional or alternative aspect of the present disclosure is a method utilizing an article, including forming an electrical assembly, and encapsulating the electrical assembly in an encapsulation material after the forming.

### BRIEF DESCRIPTION OF THE DRAWINGS

FIG. 1 is a schematic diagram of a first bus bar and a first PV cell positioned between the first bus bar and a light incident side of a PV module.

FIG. 2 is a schematic diagram of a second bus bar and a second PV cell positioned between the second bus bar and a light incident side of a PV module.

FIG. 3 is an alternate embodiment of a second bus bar and a second PV cell positioned between the second bus bar and a light incident side of a PV module.

FIG. 4 is a schematic diagram of a PV module.

FIG. 5 is a schematic side view of an article of manufacture including a PV module.

### DETAILED DESCRIPTION

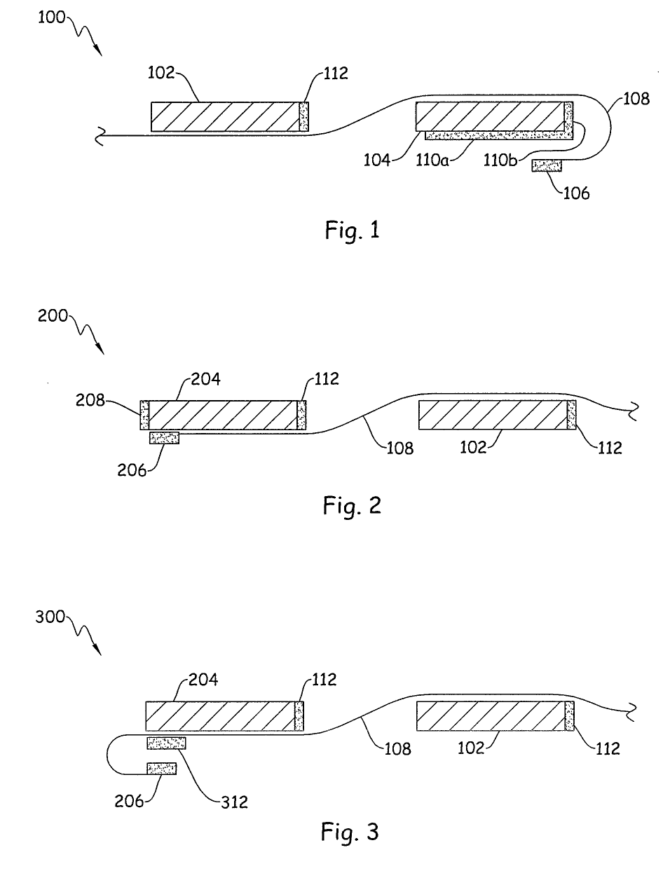

Referencing FIG. 1, an illustration 100 of a portion of a PV module is shown. A first PV cell 104, is electrically coupled to a first bus bar 16. A PV cell as utilized herein includes an element formed from a PV material, which may be any material that generates an electrical response to incident electromagnetic (EM) radiation, and in certain embodiments includes any material that generates a commercially feasible electrical response to EM radiation, and/or that generates an electrical response to incident EM radiation within at commercially feasible frequencies. Commercially feasible should be understood broadly and can include at least the quantity of electricity generated, the availability of a type and/or quantity of EM radiation, and may further be application dependent. Application dependence can relate to, without limitation, the surface area of the application, the orientation of an installation surface of the application, the electrical requirements of the application, the availability of alternative electricity sources at the location of the application, the sensitivity of the application to capital or operational costs. Example and non-limiting PV materials include copper chalcogenide type cells (e.g. copper indium gallium selenides, copper indium selenides, copper indium gallium sulfides, copper indium sulfides, copper indium gallium selenides sulfides, etc.), amorphous silicon cells, crystalline silicon cells, thin-film III-V cells, organic photovoltaics, nanoparticle photo-voltaics, dye sensitized solar cells, and/or combinations of the described materials.

Conductive elements 108, of which a single connection is shown for illustration, connect the first PV cell 104 to another PV cell 102 and to the first bus bar 106. In the illustration 100, a dielectric material 110a is positioned between the first bus bar 106 and the first PV cell 104, for example to ensure electrical separation between the first PV cell 104 and the first bus bar 106, except through the conductive elements 108. In certain embodiments, the dielectric material includes a portion 110b positioned on an outside portion of the first PV cell 104. In the illustration 100, the first PV cell 104 is a terminal PV cell at one end of a number of PV cells which together form a PV module.

In certain embodiments, adjacent pairs of PV cells 102, 104 have a dielectric 112 positioned therebetween. In the illustration 100, the light incident side of a PV module including the first PV cell 104 is above the first PV cell 104, and the first PV cell 104 is positioned between the light incident side and the first bus bar 106. Accordingly, the first bus bar 106 does not shade any of the first PV cell 104 or other PV cells 102, and the first bus bar 106 does not require any reserve space and therefore does not compete with PV cells for space within the active solar area of a device including the PV module. The first PV cell 104 is illustrated directly above the first bus bar 106, although the first PV cell 104 may be positioned anywhere that is between the first bus bar 106 and the light incident side, for example with the first bus bar 106 positioned fully or partially beneath one or more of the other PV cells in the PV module.

Referencing FIG. 2, an illustration 200 of a portion of a PV module is shown. The illustration 200 includes a second PV cell, such as a second PV cell 204, electrically coupled to a second bus bar 206. The illustration 200 includes the second bus bar 206 physically coupled to the PV cell 204, such as by direct contact through welding or an adhesive. However, the electrical coupling of the second bus bar 206 and the second PV cell 204 includes any mechanism understood in the art. In the illustration 200, the second bus bar 206 is electrically coupled to the opposing side of the second PV cell 204 rather than the light incident side, although connection to either side is contemplated. Conductive elements 108 electrically couple the second PV cell 204 to another PV cell 102. A dielectric 112 is positioned between adjacent PV cells. Referencing FIG. 3, the second bus bar 206 may be displaced from the second PV cell 204. The second bus bar 206 displaced from the second PV cell 204 is electrically coupled, for example with wires, and may further be isolated from the second cell 204, for example with a dielectric 312, to ensure that only the designated electrical path connects the second bus bar 206 to the second PV cell 204.

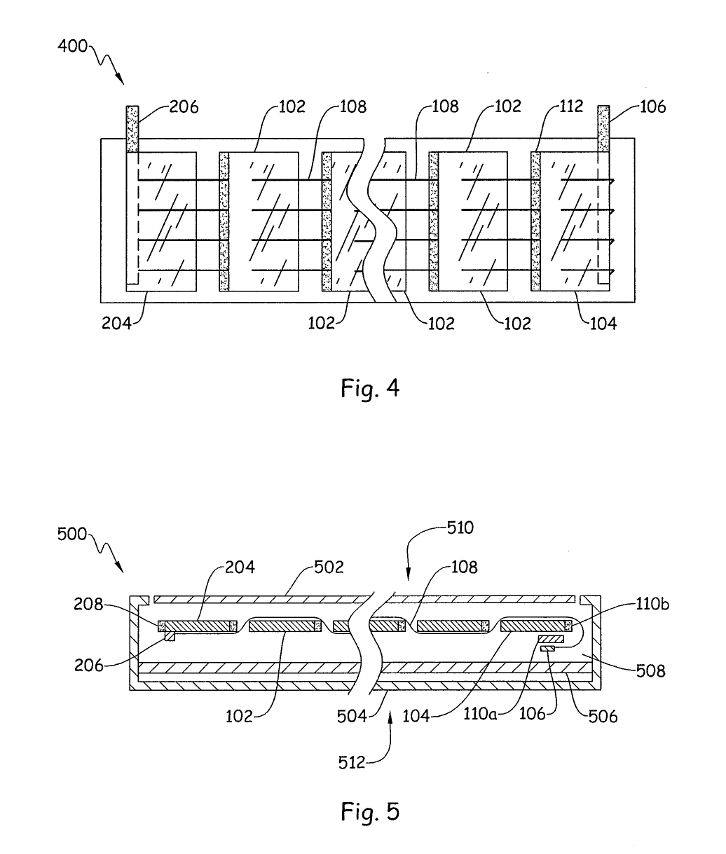

Referencing FIG. 4, an article 400 includes a PV module having a number of PV cells (e.g. PV cells 102, 104, 204), where each adjacent pair of the PV cells includes a dielectric 112 therebetween. In certain embodiments, an apparatus, for example a building integrated material unit such as a roofing shingle, includes a number of PV modules. Additionally or alternatively, each of the bus bars 106, 206 may electrically couple a number of the PV modules together, for example with the first bus bar 106 coupled to one end of each of the modules and with the second bus bar 206 coupled to a second end of each of the modules. Where multiple PV modules are present, the modules may be electrically coupled in series, parallel, and/or mixed series-parallel according to the desired electrical characteristics of the PV module group.

The dielectric 112 is shown in each instance within the article 400 as being on one of the PV cells, although both or either of the PV cells may have the dielectric coupled thereto. Additionally or alternatively, the dielectric may be positioned between the PV cells, without being coupled to either one. The sizing and positioning of the dielectric 112 between adjacent PV cells to provide sufficient electrical isolation is a mechanical step for one of skill in the art having the benefit of the disclosure herein. The PV cells 102, 104, 204 are electrically connected with a number of conductive elements 108, forming a module circuit. The module circuit of the article 400 is depicted as a series circuit. However, the module circuit may be series, parallel, and/or mixed series-parallel.

The article 400 includes a first bus bar 106 coupled to a first electrical extremity of the module circuit, and a second bus bar 206 coupled to a second electrical extremity of the module circuit. The first bus bar 106 is positioned below a first one of the PV cells 104, and thereby the first PV cell 104 is positioned between the first bus bar 106 and a light incident side of the article 400. The second bus bar 206 is positioned below a second one of the PV cells 204, and thereby the second PV cell 204 is positioned between the second bus bar 206 and a light incident side of the article 400. It is contemplated that the bus bars 106, 206 are positioned under (e.g. a PV cell interposed between the light incident side and the bus bar is “above” the bus bar) one or more PV cells that are not the terminal cells, and accordingly it is further contemplated that the first PV cell 104 and/or the second PV cell 204 are not electrical extremities of the PV module. In certain embodiments, the bus bars 106, 206 may be positioned under the same PV cell, and/or may share one or more PV cells that the bus bars 106, 206 are positioned under.

Embodiments described herein include a single bus bar coupled to each electrical extremity of the module circuit for clarity of the description and the depictions. However, in certain embodiments, the article 400 includes more than one bus bar at each electrical extremity of the module circuit; the number of bus bars at each electrical extremity of the module circuit is determined according to the selected interconnection scheme of the PV cells 104, 204 and is understood to one of skill in the art contemplating an interconnection scheme and having the benefit of the disclosures herein.

Although the example of FIG. 4 illustrates an article 400 having a number of PV cells 102, 104, 204, it is contemplated that a PV module may include only a single PV cell. The bus bars 106, 206 for an embodiment having a single PV cell are both positioned with the single PV cell interposed between the light incident side and the bus bars 106, 206. The bus bars 106, 206 are electrically isolated from each other, including by a dielectric or insulating material such as an encapsulation material. One of the bus bars 106, 206 may be in direct contact with the single PV cell, depending upon the electrical orientation of the single PV cell and the desired structure of the article 400, although both bus bars 106, 206 may also be electrically isolated from the single PV cell except as connected through the conductive elements 108.

It is contemplated that certain embodiments of apparatuses and articles described herein include numerous layers and/or assemblies, for example but not limited to features from various embodiments described in currently pending International patent application No. PCT/US09/042496, incorporated herein by reference in the entirety for all purposes. Referencing FIG. 5, an article 500 is schematically depicted in a cutaway side view. The article 500 includes a number of PV cells, such as PV cells 102, 104, 204, which are electrically connected to form a module circuit. The first PV cell 104 is positioned at a first electrical extremity of the module circuit, and the second PV cell 204 is positioned at a second electrical extremity of the module circuit. The first bus bar 106 is electrically coupled to the first one of the PV cells 104, and the second bus bar 206 is electrically coupled to the second one of the PV cells 204. The module circuit, first bus bar 106, and second bus bar 206 together form an electrical assembly. The article 500 further includes an encapsulation material 508 that encapsulates the electrical assembly. The encapsulation material 508 may be provided in one or more layers, and/or may be molded or assembled in any other manner. Example and non-limiting encapsulant materials include a poly-olefin, an ethyl-vinyl-acetate, and/or a polymeric insulating material. One or more layers of the encapsulation material 508 may be formed from the same or distinct materials.

The example article 500 includes a transparent sheet 502 provided on the light incident side 510 of the article 500. The sheet 502 is transparent to the appropriate light frequencies for the PV cells 104, 204, 102, which may include all or portions of the visible light spectrum, and may alternatively or additionally include portions of the light spectrum above or below the visible frequencies. The sheet 502 may provide physical protection and/or environmental protection. In certain embodiments, additional layers may be provided above the PV cells 104, 204, 102 to provide additional protection or desired features for the article 500.

The example article 500 further includes a structural backing 504 defining a shape of the article 500. The structural backing 504 is provided on the opposing side 512, relative to the light incident side 510, of the article. The structural backing 504, in the example, is coupled to the sheet 502, although additional layers or coupling features may be present. The article 500 further includes an environmental barrier sheet 506, for example to prevent intrusion of water and/or other materials into the electrical assembly, and/or to provide electrical isolation for example from a roofing or installation surface. Any additional packaging, wire mesh, barrier layers, structural layers and/or support materials may be present in the article 500. The described elements of the article 500 are non-limiting examples, and described elements may be present or lacking in particular embodiments. In certain embodiments, the article 500 is formed as a roofing shingle or as a unit sized to substitute for a group of roofing shingles. In certain embodiments, the article 500 is formed as a unit of building siding. In certain embodiments, the article 500 is formed as a building integrated PV product. In certain embodiments, the article 500 is of the same thickness as a replacement conventional building article, is not of a greater thickness than a replacement conventional building article, or is not of a greater thickness than a specified thickness for a building article. In certain embodiments, the article 500 does not include a junction box.

The example article 500 includes an opposing side 512 from the light incident side 510, where the second bus bar 206 is electrically coupled to the opposing side 512 of the second PV cell 204. The article 500 further includes the structural backing 504 defining a unit shape of a construction material unit (e.g. a roofing shingle, a siding unit, and/or groups thereof), an encapsulation material 508 interposed between the structural backing 504 and the second bus bar 206, and the second bus bar 206 interposed between the encapsulation material 508 and the second PV cell 204. The article 500 further includes the encapsulation material 508 interposed between the structural backing 504 and the first bus bar 106, where the first bus bar 106 is interposed between the encapsulation material 508 and the first PV cell 104. In the example of FIG. 5, the bus bars 106, 206 may be in contact with the cells 104, 204 where the electrical orientation of the cells 104, 204 is favorable, or separated from the cells 104, 204 and isolated with encapsulation material 508 and/or with a dielectric 110a. The bus bars 106, 206 may be separated from the cells 104, 204 regardless of the electrical orientation of the cells 104, 204, depending upon the desired structure of the article 500.

The schematic flow description which follows provides an illustrative embodiment of performing procedures for utilizing a PV article. Operations illustrated are understood to be exemplary only, and operations may be combined or divided, and added or removed, as well as re-ordered in whole or part, unless stated explicitly to the contrary herein. Certain operations illustrated may be implemented by a computer executing a computer program product on a computer readable medium, where the computer program product comprises instructions causing the computer to execute one or more of the operations, or to issue commands to other devices to execute one or more of the operations.

An example procedure includes an operation to form an electrical assembly including a module circuit having a number of electrically coupled PV cells, a first bus bar electrically coupled to a first extremity of the module circuit, and a second bus bar electrically coupled to a second extremity of the module circuit. The electrical coupling of the PV cells may be series, parallel, or mixed series-parallel. The procedure further includes an operation to encapsulate the electrical assembly in an encapsulation material after the forming.

Any numerical values recited in the above application include all values from the lower value to the upper value in increments of one unit provided that there is a separation of at least 2 units between any lower value and any higher value. As an example, if it is stated that the amount of a component or a value of a process variable such as, for example, temperature, pressure, time and the like is, for example, from 1 to 90, further including from 20 to 80, also including from 30 to 70, it is intended that values such as 15 to 85, 22 to 68, 43 to 51, 30 to 32 etc. are expressly enumerated in this disclosure. One unit is considered to be the most precise unit disclosed, such as 0.0001, 0.001, 0.01 or 0.1 as appropriate. These are only examples of what is specifically intended and all possible combinations of numerical values between the lowest value and the highest value enumerated are to be considered to be expressly stated in this disclosure in a similar manner.

Unless otherwise stated, all ranges include both endpoints and all numbers between the endpoints. The disclosures of all articles and references, including patent applications and publications, are incorporated by reference for all purposes. The use of the terms “comprising” or “including” describing combinations of elements, ingredients, components or steps herein also contemplates embodiments that consist essentially of the elements, ingredients, components or steps. The use of the articles “a” or “an,” and/or the disclosure of a single item or feature, contemplates the presence of more than one of the item or feature unless explicitly stated to the contrary.

Example embodiments of the present invention have been disclosed. A person of ordinary skill in the art will realize however, that certain modifications to the disclosed embodiments come within the teachings of this disclosure. Therefore, the following claims should be studied to determine the true scope and content of the invention.

What is claimed is:

1. A photovoltaic module_comprising:
a photovoltaic (PV) module comprising at least one PV cell which is selected from the group of copper chalcogenide type cells, amorphous silicon cells, thin film III-V cells, organic photovoltaics, nanoparticle photo-voltaics, and dye sensitized solar cells;
a plurality of conductive elements, each of the conductive elements electrically coupled to the at least one PV cell and forming a module circuit;
a first bus bar coupled to a first electrical extremity of the module circuit, wherein the PV module further comprises a light incident side, and wherein a PV cell from the at least one PV cell is interposed between the first bus bar and the light incident side; and
a second bus bar wherein a PV cell from the at least one PV cell is interposed between the second bus bar and the light incident side and the second bus bar is electrically coupled to an opposing side of the PV cell.

2. The module according to claim 1:
wherein the at least one PV cell comprises a plurality of PV cells, each adjacent pair of the PV cells having a dielectric positioned there between;
wherein the plurality of conductive elements are electrically coupled to at least one of the plurality of PV cells, and wherein the conductive elements electrically connect the PV cells; and
wherein the plurality of PV cells comprises a first PV cell interposed between the first bus bar and the light incident side of the first PV cell, and a second PV cell interposed between the second bus bar and the light incident side of the second PV cell wherein the second bus bar is electrically coupled to an opposing side of the second PV cell.

3. The module cture according to claim 2, further comprising the first bus bar electrically coupled to the first one of the PV cells on the light incident side, the article further comprising a bus bar separation dielectric positioned between the first bus bar and the first one of the PV cells.

4. The module according to claim 3, wherein the bus bar separation dielectric further includes a portion positioned on an outer portion of the first one of the PV cells.

5. The module according to claim 2, wherein the second bus bar is physically coupled to the opposing side of the second cell by direct contact.

6. The module according to claim 2, the article comprising a dielectric positioned between the second bus bar and the second one of the PV cells.

7. The module according to claim 2, wherein the module circuit comprises a circuit arrangement selected from the arrangements consisting of a series circuit, a parallel circuit, and a series parallel circuit.

8. The module according to claim 1, wherein the module circuit, the first bus bar, and the second bus bar form an electrical assembly, the article further comprising at least one encapsulation material structured to encapsulate the electrical assembly.

9. A method utilizing the module according to claim 8, the method comprising forming the electrical assembly, and encapsulating the electrical assembly in the at least one encapsulation material after the forming.

10. The module according to claim 2, wherein the PV module further comprises an opposing side from the light incident side, and wherein the second bus bar is electrically coupled to the opposing side of the second one of the PV cells, material unit, an encapsulation material interposed between the structural backing and the second bus bar, and wherein the second bus bar is interposed between the encapsulation material and the second one of the PV cells.

11. The module of claim 10, further comprising the encapsulation material interposed between the structural backing and the first bus bar, and wherein the first bus bar is interposed between the encapsulation material and the first one of the PV cells.

12. The module according to claim 1, wherein the module is a roofing shingle.
